(19) United States
(12) Patent Application Publication
(10) Pub. No.: US 2024/0215313 A1
(43) Pub. Date: Jun. 27, 2024

(54) DISPLAY PANEL AND DISPLAY DEVICE

(71) Applicant: Shenzhen China Star Optoelectronics Semiconductor Display Technology Co., Ltd., Shenzhen (CN)

(72) Inventor: Qian MA, Shenzhen (CN)

(73) Assignee: Shenzhen China Star Optoelectronics Semiconductor Display Technology Co., Ltd., Shenzhen (CN)

(21) Appl. No.: 18/193,913

(22) Filed: Mar. 31, 2023

(30) Foreign Application Priority Data
Dec. 22, 2022 (CN) 202211659341.0

(51) Int. Cl. H10K 59/121; H10K 59/126

(52) U.S. Cl. CPC H10K 59/1213; H10K 59/126

(57) ABSTRACT

Disclosed are a display panel and a display device, including a first transistor and a second transistor electrically connected to each other, wherein the first transistor includes a first active portion made of a low-temperature polysilicon material, and the second transistor comprises a second active portion made of a metal oxide material and a second gate. The display panel further includes a base, the first active portion disposed on the base, the second active portion disposed on a side of the first active portion away from the base, and the second gate located on a side of the second active portion away from the first active portion. An orthographic projection of the second active portion on the base at least partially overlaps an orthographic projection of the first active portion on the base. The present disclosure can improve the space utilization and resolution of display panel.

### CROSS-REFERENCE TO RELATED APPLICATIONS

The present application claims priority to Chinese Patent Application No. 202211659341.0, filed on Dec. 22, 2022, the contents of which are incorporated herein by reference in its entirety.

### TECHNICAL FIELD

The present disclosure relates to a display technology, and in particular, to a display panel and a display device having the same.

### BACKGROUND

Generally, in a low-temperature polycrystalline oxide (LTPO) array substrate, thin film transistors (TFTs) are prepared by two materials, a low-temperature polysilicon (LTPS) and a metal oxide such as indium gallium zinc oxide (IGZO). LTPS is responsible for driving the TFT and the metal oxide is responsible for switching the TFT. The LTPO array substrate has the advantages of higher charge mobility and lower off-state leakage current, and can reduce overall power consumption during screen operation, thereby achieving power saving.

However, in an existing display panel having the LTPO array substrate, an electrode plate is formed above a gate of the low-temperature polysilicon TFT, so that a large space needs to be occupied. In addition, the low-temperature polysilicon TFT and the metal oxide TFT are independently disposed in the LTPO array substrate, so that a larger space needs to be occupied, which is disadvantageous to the improvement of the space utilization rate and resolution of the display panel.

### SUMMARY

An embodiment of the present disclosure provides a display panel and a display device, which can reduce occupied space of a first transistor and a second transistor, and improve the space utilization rate and resolution of the display panel.

An embodiment of the present disclosure provides a display panel including a first transistor and a second transistor electrically connected to each other, wherein the first transistor comprises a first active portion made of a low-temperature polysilicon material, and the second transistor comprises a second active portion made of a metal oxide material and a second gate:
wherein the display panel further comprises:
a base;
a first active layer disposed on the base and comprising the first active portion;
a second active layer disposed on a side of the first active layer away from the base and comprising the second active portion located on a side of the first active portion away from the base; and
a first metal layer disposed on a side of the second active layer away from the first active layer and comprising the second gate located on a side of the second active portion away from the first active portion;
wherein an orthographic projection of the second active portion on the base at least partially overlaps an orthographic projection of the first active portion on the base.

According to the above objective of the present disclosure, an embodiment of the present disclosure further provides a display device including a display panel, wherein the display panel includes a first transistor and a second transistor electrically connected to each other, the first transistor comprises a first active portion made of a low-temperature polysilicon material, and the second transistor comprises a second active portion made of a metal oxide material and a second gate:
the display panel further comprises:
a base;
a first active layer disposed on the base and comprising the first active portion;
a second active layer disposed on a side of the first active layer away from the base and comprising the second active portion located on a side of the first active portion away from the base; and
a first metal layer disposed on a side of the second active layer away from the first active layer and comprising the second gate located on a side of the second active portion away from the first active portion;
wherein an orthographic projection of the second active portion on the base at least partially overlaps an orthographic projection of the first active portion on the base.

The present disclosure has the advantages that, by designing that the first active portion of the first transistor at least partially overlaps the second active portion of the second transistor, the first transistor can at least partially overlap the second transistor, thereby effectively reducing the occupied space of the first transistor and the second transistor, and improving the space utilization rate and the resolution of the display panel.

### BRIEF DESCRIPTION OF THE DRAWINGS

The specific embodiments of the present disclosure will be described in detail below with reference to the accompanying drawings, in order to make the technical solutions and beneficial effects of the present disclosure apparent.

FIG. 1 is a schematic cross-sectional view of a display panel according to a prior art.

FIG. 2 is a schematic cross-sectional view of a display panel according to an embodiment of the present disclosure.

FIG. 3 is another schematic cross-sectional view of a display panel according to an embodiment of the present disclosure.

FIG. 4 is another schematic cross-sectional view of a display panel according to another embodiment of the present disclosure.

FIG. 5 is another schematic cross-sectional view of a display panel according to another embodiment of the present disclosure.

FIG. 6 is a flowchart of a method for manufacturing a display panel according to another embodiment of the present disclosure.

### DETAILED DESCRIPTION OF THE EMBODIMENTS

Technical solutions in the embodiments of the present disclosure will be described fully and completely below with reference to the accompanying drawings. It is apparent that the described embodiments are only part of the embodiments of the present disclosure, rather than all of the embodiments. Based on the embodiments of the present disclosure, all other embodiments obtained by a person skilled in the art without involving any inventive effort are within the scope of the present disclosure.

The following disclosure provides many different embodiments or examples to implement different structures of the present disclosure. In order to simplify the present disclosure, specific examples are illustrated below for components and arrangements therein. Certainly, they are merely exemplary examples and are not intended to limit the present disclosure. In addition, reference numerals and/or reference letters may be repeated in various examples of the present disclosure for purposes of simplicity and clarity, and the repetition does not indicate a relationship among the various embodiments and/or arrangements discussed. In addition, the present disclosure provides various examples of specific processes and materials, but one of ordinary skill in the art will recognize the application of other processes and/or the use of other materials.

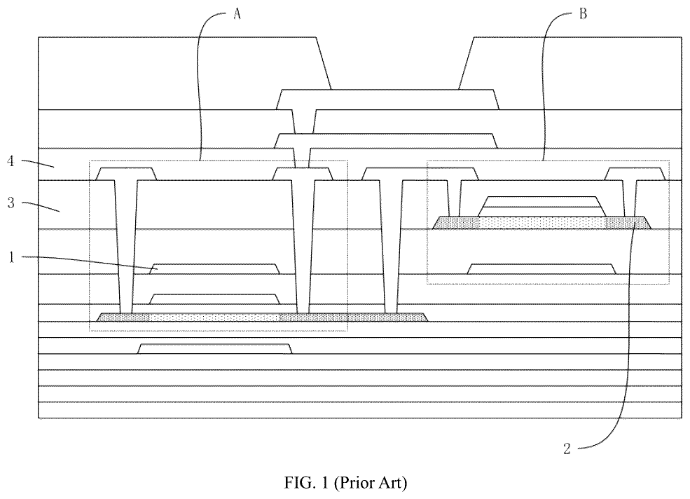

Referring to FIG. 1, in a display panel having an LTPO array substrate in a prior art, it is necessary to prepare a low-temperature polysilicon thin film transistor A and a metal oxide thin film transistor B on the substrate, and a capacitor plate 1 is formed above a gate of the low-temperature polysilicon thin film transistor A. The capacitor plate 1 has a relatively large area, and thus it needs to occupy a large space. In addition, the low-temperature polysilicon thin film transistor A and the metal oxide thin film transistor B are independently disposed in the LTPO array substrate from each other, so that the low-temperature polysilicon thin film transistor A and the metal oxide thin film transistor B also need to occupy a large space, which is disadvantageous for the improvement of the space utilization rate and the resolution of the display panel.

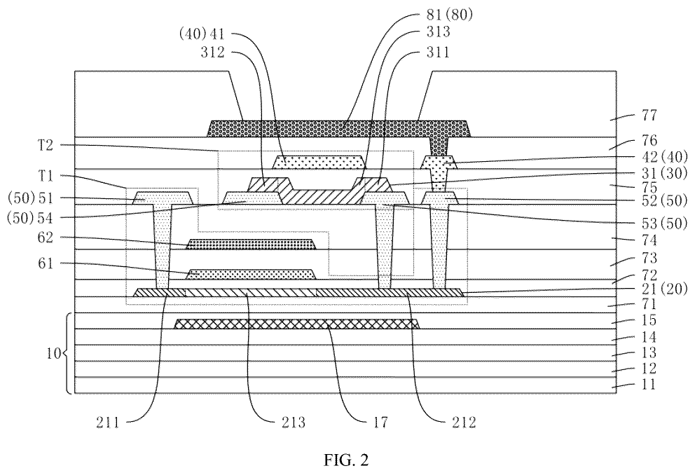

Referring to FIG. 2, the present disclosure provides a display panel according to an embodiment, including a first transistor T1 and a second transistor T2 electrically connected to each other. The first transistor T1 includes a first active portion 21 made of a low-temperature polysilicon material, and the second transistor T2 includes a second gate 41 and a second active portion 31 made of a metal oxide material.

According to an embodiment of the present disclosure, the display panel further includes a base 10, a first active layer 20, a second active layer 30, and a first metal layer 40. The first active layer 20 is disposed on the base 10 and includes the first active portion 21. The second active layer 30 is disposed on a side of the first active layer 20 away from the base 10, and includes the second active portion 31 located on a side of the first active portion 21 away from the base 10. The first metal layer 40 is disposed on a side of the second active layer 30 away from the first active layer 20, and includes a second gate 41 located on a side of the second active portion 31 away from the first active portion 21.

An orthographic projection of the second active portion 31 on the base 10 at least partially overlaps an orthographic projection of the first active portion 21 on the base 10.

In an implementation of an embodiment of the present disclosure, the first active portion 21 of the first transistor T1 at least partially overlaps the second active portion 31 of the second transistor T2, so that the first transistor T1 at least partially overlaps the second transistor T2, thereby effectively reducing the occupied space of the first transistor T1 and the second transistor T2, and improving the space utilization rate and the resolution of the display panel. In addition, in an embodiment of the present disclosure, the second gate 41 of the second transistor T2 is disposed on the side of the second active portion 31 away from the first active portion 21, thereby preventing a spatial interference between the second gate 41 and an electrode plate 62, reducing generation of parasitic capacitance, and improving reliability and stability of the display panel, compared to the prior art shown in FIG. 1,

Specifically, referring to FIG. 2, the display panel includes the base 10, a driving circuit layer disposed on the base 10, and a light-emitting functional layer disposed on a side of the driving circuit layer away from the base 10.

The base 10 may include a first flexible substrate layer 11, a first water-oxygen barrier layer 12, a second flexible substrate layer 13, a second water-oxygen barrier layer 14, and a third water-oxygen barrier layer 15 that are stacked in sequence. The material of the first flexible substrate layer 11 or the second flexible substrate layer 13 may comprise a polyimide material, and the material of the first water-oxygen barrier layer 12, the second water-oxygen oxygen barrier layer 14, or the third water-oxygen barrier layer 15 may comprise at least one of a silicon oxide material and a silicon nitride material.

The driving circuit layer is disposed on the base 10. The display panel further includes a buffer layer 71 disposed between the base 10 and the driving circuit layer. The driving circuit layer includes the first transistor T1 and the second transistor T2 disposed on the buffer layer 71. The first transistor T1 is electrically connected to the second transistor T2. The first transistor T1 includes the first active portion 21, a first gate 61, an electrode plate 62, a first source 51, and a first drain 52. The second transistor T2 includes the second active portion 31, the second gate 41, a second source 53, and a second drain 54.

According to an embodiment of the present disclosure, the driving circuit layer includes the first active layer 20 disposed on the buffer layer 71, a first insulating layer 72 covering the first active layer 20, the first gate 61 disposed on the first insulating layer 72, a gate insulating layer 73 covering the first gate 61, the electrode plate 62 disposed on the gate insulating layer 73, a second insulating layer 74 covering the electrode plate 62, the second metal layer 50 disposed on the second insulating layer 74, the second active layer 30 disposed on the second metal layer 50, an inorganic passivation layer 75 covering the second metal layer 50 and the second active layer 30, the first metal layer 40 disposed on the inorganic passivation layer 75, an organic planarization layer 76 covering the first metal layer 40, an anode layer 80 disposed on the organic planarization layer 76, and a pixel definition layer 77 disposed on the anode layer 80.

Specifically, the first active layer 20 includes a first active portion 21, and the material of the first active portion 21 includes a low-temperature polysilicon material. The first gate 61 is disposed on a side of the first active portion 21 away from the base 10, and the electrode plate 62 is disposed on a side of the first gate 61 away from the first active portion 21. The second metal layer 50 includes the first source 51 and the first drain 52, both of which pass through the second insulating layer 74, the gate insulating layer 73, and the first insulating layer 72 to connect two ends of the first active portion 21.

Accordingly, the first active portion 21 includes a first source contact sub-portion 211 connected to the first source 51, a first drain contact sub-portion 212 connected to the first drain 52, and a first channel sub-portion 213 connected between the first source contact sub-portion 211 and the first drain contact sub-portion 212.

In an embodiment, a conductorization treatment may be performed on the first source contact sub-portion 211 and the first drain contact sub-portion 212, such that the resistivity of the material of the first source contact sub-portion 211 and the resistivity of the material of the first drain contact sub-portion 212 are less than the resistivity of the material of the first channel sub-portion 213.

The first transistor T1 may be a double-gate thin film transistor, and the electrode plate 62 and the first gate 61 may constitute a storage capacitor of a sub-pixel unit, thereby improving the continuous display effect of the display device.

The second metal layer 50 further includes the second source 53 and the second drain 54. The second active layer 30 includes the second active portion 31, part of which is located on the second insulating layer 74 and part of which extends to sides of the second source 53 and the second drain 54 away from the first active portion 21. The second active portion 31 includes a second source contact sub-portion 311 located on a side of the second source 53 away from the first active portion 21, a second drain contact sub-portion 312 located on a side of the second drain 54 away from the first active portion 21, and a second channel sub-portion 313 connected between the second source contact sub-portion 311 and the second drain contact sub-portion 312. The second channel sub-portion 313 is located between the second source 53 and the second drain 54.

It is to be noted that in a manufacturing process, the second source 53 and the second drain 54 are formed first, then the second active portion 31 is formed, and thus a length of the second channel sub-portion 313 between the second source 53 and the second drain 54 can be controlled by a distance between the second source 53 and the second drain 54, thereby achieving the second transistor T2 having a short channel.

In an embodiment of the present disclosure, the orthographic projection of the second active portion 31 on the base 10 at least partially overlaps the orthographic projection of the first active portion 21 on the base 10, so that the second transistor T2 at least partially overlaps the first transistor T1, thereby reducing the occupied space proportion of the first transistor T1 and the second transistor T2, and improving the space utilization rate and the resolution of the display panel. In addition, in the embodiments of the present disclosure, the area of the electrode plate 62 is large, the second gate 41 of the second transistor T2 is disposed on the side of the second active portion 31 away from the first active portion 21, so that a spatial interference between the second gate 41 and the electrode plate 62 can be avoided, and parasitic capacitance can be reduced, thereby improving reliability and stability of the display panel.

The first metal layer 40 includes the second gate 41, and the second gate 41 is located on the side of the second active portion 31 away from the first active portion 21.

In an embodiment, the second channel sub-portion 313 is connected between the second source 53 and the second drain 54. After a voltage is applied to the second gate 41, a current channel may be formed in the second channel sub-portion 313, and in turn a current channel may be formed directly between the second source 53 and the second drain 54, without performing the conductorization treatment on the second active portion 31.

With respect to the prior art, as shown in FIG. 1, the active layer 2 of the metal oxide thin film transistor B needs to be subjected to the conductorization treatment, so as to form an electrical connection between the source and the drain. However, the active layer 2 of the metal oxide thin film transistor B is prepared using a metal oxide, and can be easily influenced by a thermal process in a subsequent film layer deposition process, so that carriers generated by the conductorization portion diffuse toward the channel portion of the active layer, resulting in the instability of the metal oxide thin film transistor B. In addition, in the prior art, two inorganic insulating layers, an interlayer insulating layer 3 and a passivation layer 4, are disposed above the active layer 2 of the metal oxide thin film transistor B. In the embodiments of the present disclosure, as shown in FIG. 2, the second active portion 31 is disposed above the first transistor T1, and only the inorganic passivation layer 75 is disposed above the second active portion 31, so that the number of the inorganic insulation layers above the second active portion 31 can be reduced, and further, the influence of the thermal process during the formation of the inorganic insulation layer on the second active portion 31 can be reduced, thereby improving the stability and the yield of the second transistor T2.

Further, as shown in FIG. 2, the second gate 41 is disposed above the second active portion 31 and the area covered by the second gate 41 is increased, so that the second channel sub-portion 313 corresponding to the second gate 41 is connected between the second source 53 and the second drain 54, and a current channel can be directly formed between the second source 53 and the second drain 54. Therefore, there is no need to perform a conductorization process to the second active portion 31, which saves the conductorization process, and can avoid the phenomenon that carrier diffusion occurs due to the influence of the thermal process on the second active portion 31, thereby improving the stability and yield of the second transistor T2.

In an embodiment, the second active portion 31 does not need to be performed the conductorization process, both of the resistivity of the material of the second source contact sub-portion 311 and the resistivity of the material of the second drain contact sub-portion 312 are equal to the resistivity of the material of the second channel sub-portion 313.

In an embodiment of the present disclosure, the first source 51, the first drain 52, the second source 53, and the second drain 54 may be formed in the same process, which can save steps of the process. The second active portion 31 is located between the first source 51 and the first drain 52, the second drain 54 is disposed at an interval from the first source 51, and the second source 53 is connected to the first drain 52 by the first drain contact sub-portion 212. That is, the second source 53 may penetrate through the second insulating layer 74, the gate insulating layer 73, and the first insulating layer 72 to connect with the first drain contact sub-portion 212.

In an embodiment, the display panel further includes a light shielding layer 17 disposed in the base 10, and an orthographic projection of the first channel sub-portion 213 on the base 10 is located within a coverage area of an orthographic projection of the light shielding layer 17 on the base 10.

It is to be noted that, in the embodiments of the present disclosure, the light-shielding layer 17 is formed in the base 10, and the light-shielding layer 17 may be located between any two adjacent film layers in the base 10, for example, on the second water-oxygen barrier layer 14 and covered by the third water-oxygen barrier layer 15.

In an embodiment, the coverage area of the light shielding layer 17 is increased, so that an orthographic projection of the second channel sub-portion 313 on the base 10 is within the coverage area of the orthographic projection of the light shielding layer 17 on the base 10, as shown in FIG. 2. Therefore, light can be blocked from irradiating from the side of the second active portion 31 close to the base 10 to the second channel sub-portion 313, thereby improving the stability of the second transistor T2.

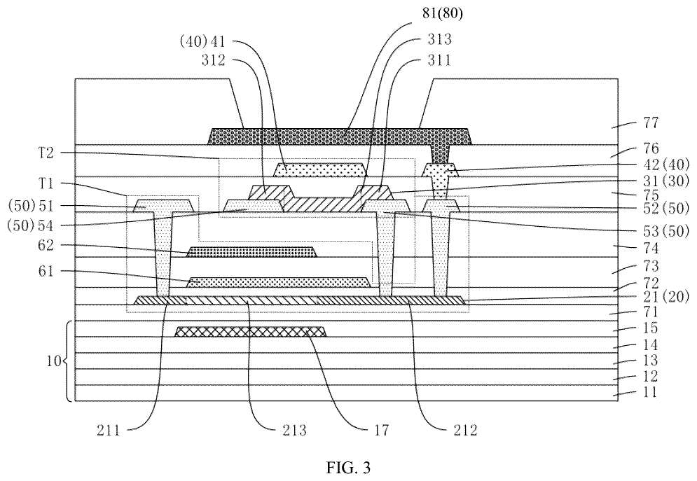

In an embodiment, the coverage area of the first gate 61 is increased, so that the orthographic projection of the second channel sub-portion 313 on the base 10 is within the coverage area of an orthographic projection of the first gate 61 on the base 10, as shown in FIG. 3. Therefore, light can be blocked from irradiating from the side of the second active portion 31 close to the base 10 to the second channel sub-portion 313, thereby improving the stability of the second transistor T2.

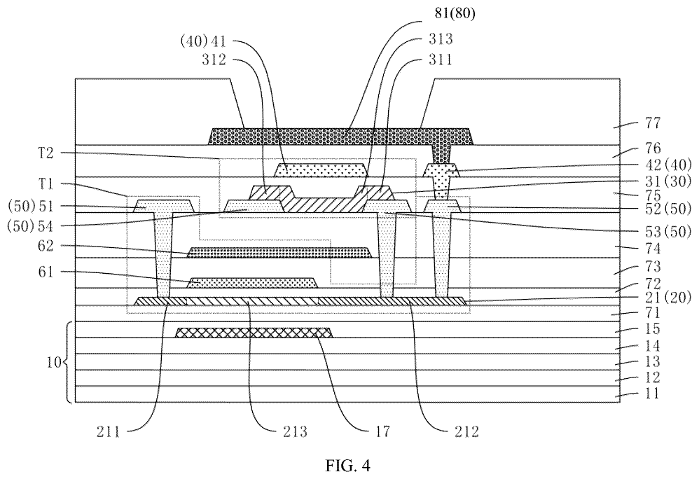

In an embodiment, the coverage area of the electrode plate 62 is increased, so that the orthographic projection of the second channel sub-portion 313 on the base 10 is within the coverage area of the orthographic projection of the electrode plate 62 on the base 10, as shown in FIG. 4. Therefore, light can be blocked from irradiating from the side of the second active portion 31 close to the base 10 to the second channel sub-portion 313, thereby improving the stability of the second transistor T2.

In an embodiment, the coverage area of at least two of the light-shielding layer 17, the first gate 61, and the electrode plate 62 may be increased, such that the orthographic projection of the second channel sub-portion 313 on the base 10 is within the coverage area of at least two of the orthographic projection of the light-shielding layer 17 on the base 10, the orthographic projection of the first gate 61 on the base 10, and the orthographic projection of the electrode plate 62 on the base 10.

In addition, the display panel further includes an anode layer 80 disposed on a side of the first metal layer 40 away from the second active layer 30. The anode layer 80 includes an anode 81 electrically connected to the first transistor T1, and the anode 81 is electrically connected to the first drain 52.

In an embodiment, the first metal layer 40 further includes an adapting portion 42. The anode 81 is connected to the first drain 52 by the adapting portion 42. In the embodiments of the present disclosure, the anode 81 is prepared in the same layer as the adapting portion 42, thereby simplifying the process procedure and reducing the process cost.

Here, the orthographic projection of the second channel sub-portion 313 on the base 10 is within the coverage area of an orthographic projection of the anode 81 on the base 10, so that light of the side of the second active portion 31 away from the base 10 can be blocked from being irradiated to the second channel sub-portion 313, thereby further improving the stability of the second transistor T2.

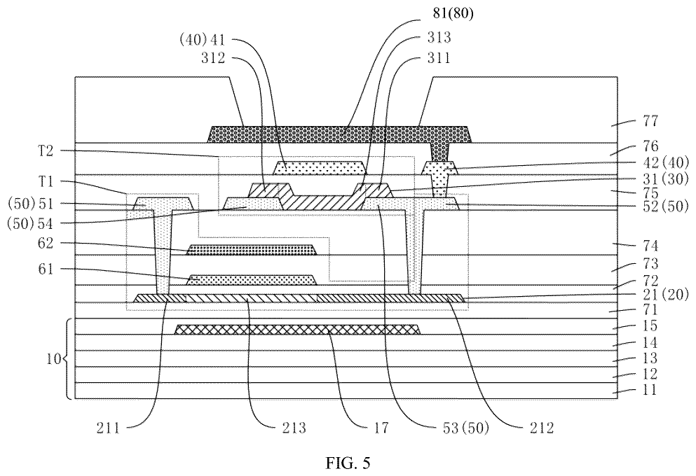

In an embodiment, referring to FIG. 5, the second source 53 and the second drain 54 are connected to each other. That is, the second source 53 is integrated with the second drain 54, thereby further simplifying the process and reducing the process cost.

According to the embodiments of the present disclosure, the first active portion 21 of the first transistor T1 at least partially overlaps the second active portion 31 of the second transistor T2, so that the first transistor T1 at least partially overlaps the second transistor T2, thereby effectively reducing the occupied space of the first transistor T1 and the second transistor T2, and improving the space utilization rate and the resolution of the display pane. In addition, in the embodiments of the present disclosure, the second gate 41 of the second transistor T2 is disposed on the side of the second active portion 31 away from the first active portion 21, so that spatial interference between the second gate 41 and the electrode plate can be avoided, parasitic capacitance can be reduced, thereby improving the reliability and stability of the display panel.

In addition, an embodiment of the present disclosure provides a method for manufacturing a display panel described in the above embodiments. Referring to FIG. 2, the method for manufacturing the display panel includes the following steps:
preparing a base 10.

The first active layer 20 is formed on the base 10. The first active layer 20 includes the first active portion 21 of the first transistor T1, and the first active portion 21 is made of a low-temperature polysilicon material.

The second active layer 30 is formed on the side of the first active layer 20 away from the base 10. The second active layer 30 includes the second active portion 31 of the second transistor T2. The second active layer 30 is formed on the side of the first active portion 21 away from the base 10 and made of a metal oxide material. The orthographic projection of the second active portion 31 on the base 10 at least partially overlaps the orthographic projection of the first active portion 21 on the base 10.

The first metal layer 40 is formed on the side of the second active layer 30 away from the first active layer 20. The first metal layer 40 includes the second gate 41 of the second transistor T2, and the second gate 41 is formed on the side of the second active portion 31 away from the first active portion 21.

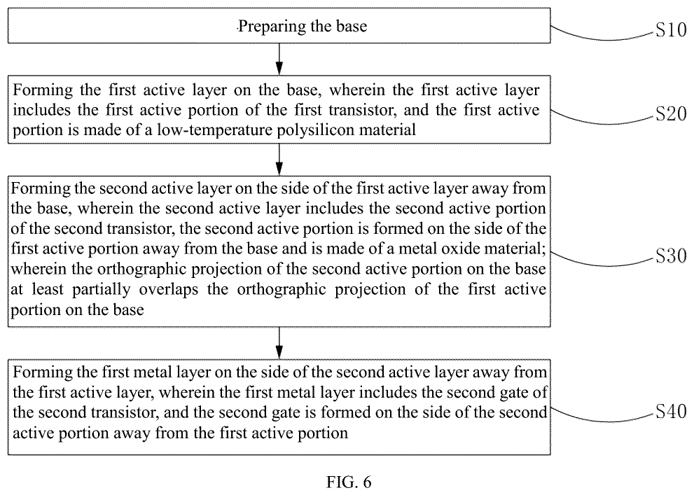

Specifically, referring to FIGS. 2 and 6, the method for manufacturing the display panel includes the following steps:

S10. preparing the base 10.

In step S10, the base 10 is provided to include the first flexible substrate layer 11, the first water-oxygen barrier layer 12, the second flexible substrate layer 13, the second water-oxygen barrier layer 14, and the third water-oxygen barrier layer 15 that are sequentially stacked. The material of the first flexible substrate layer 11 or the second flexible substrate layer 13 may include a polyimide material, and the material of the first water-oxygen barrier layer 12, the second water-oxygen barrier layer 14, or the third water-oxygen barrier layer 15 may include at least one of a silicon oxide material and a silicon nitride material.

It is to be noted that, in the embodiments of the present disclosure, the light-shielding layer 17 is formed in the base 10. The light-shielding layer 17 may be located between any two adjacent film layers in the base 10, for example, on the second water-oxygen barrier layer 14 and covered by the third water-oxygen barrier layer 15.

S20. Forming the first active layer 20 on the base 10. The first active layer 20 includes the first active portion 21 of the first transistor T1, and the first active portion 21 is made of a low-temperature polysilicon material.

In step S20, the buffer layer 71 is formed on the base 10.

Then, the first transistor T1 is formed on a side of the buffer layer 71 away from the base 10. Specifically, the first active portion 21 is formed on the buffer layer 71 by using the low-temperature polysilicon material. The first insulating layer 72 covering the first active portion 21 is formed on the buffer layer 71. The first gate 61 is formed on the first insulating layer 72 on the side of the first active portion 21 away from the base 10. The gate insulating layer 73 covering the first gate 61 is formed on the first insulating layer 72. The electrode plate 62 is formed on the gate insulating layer 73 on the side of the first gate 61 away from the first active portion 21. The second insulating layer 74 covering the electrode plate 62 is formed on the gate insulating layer 73. The first metal material layer is formed on the second insulating layer 74. The first active portion 21 includes the first channel sub-portion 213, and the first source contact sub-portion 211 and the first drain contact sub-portion 212, wherein the first source contact sub-portion 211 and the first drain contact sub-portion 212 are connected to two sides of the first channel sub-portion 213, respectively.

Next, the first metal material layer is patterned to obtain the second metal layer 50 to obtain the first source 51 and the first drain 52 of the first transistor T1. The first source 51 and the first drain 52 are connected to the first source contact sub-portion 211 and the first drain contact sub-portion 212 through the second insulating layer 74, the gate insulating layer 73, and the first insulating layer 72, respectively.

In addition, the second source 53 and the second drain 54 of the second transistor T2 are formed in the second metal layer 50. Since the second transistor T2 needs to be electrically connected to the first transistor T1, the second source 53 may also be connected to the first drain contact sub-portion 212 through the second insulating layer 74, the gate insulating layer 73, and the first insulating layer 72.

S30. Forming the second active layer 30 on the side of the first active layer 20 away from the base 10, wherein the second active layer 30 includes the second active portion 31 of the second transistor T2, the second active portion 31 is formed on the side of the first active portion 21 away from the base 10 and is made of a metal oxide material. The orthographic projection of the second active portion 31 on the base 10 at least partially overlaps the orthographic projection of the first active portion 21 on the base 10.

In step S30, the metal oxide layer is formed on the side of the second metal layer 50 away from the base 10, and the material of the metal oxide layer may be indium gallium zinc oxide.

Then, the metal oxide layer is patterned to obtain the second active layer 30, and the second active layer 30 includes the patterned second active portion 31. A part of the second active portion 31 is located on the second insulating layer 74, and a part of the second active portion 31 extends to the sides of the second source 53 and the second drain 54 away from the first active portion 21. The second active portion 31 includes the second source contact sub-portion 311 located on the side of the second source 53 away from the first active portion 21, the second drain contact sub-portion 312 located on the side of the second drain 54 away from the first active portion 21, and the second channel sub-portion 313 disposed and connected between the second source contact sub-portion 311 and the second drain contact sub-portion 312.

In the embodiments of the present disclosure, the orthographic projection of the second active portion 31 on the base 10 at least partially overlaps the orthographic projection of the first active portion 21 on the base 10, so that the second transistor T2 at least partially overlaps the first transistor T1, thereby reducing the occupied space proportion of the first transistor T1 and the second transistor T2, and improving the spatial utilization rate and resolution of the display panel.

In addition, in the embodiments of the present disclosure, the second source 53 and the second drain 54 are firstly prepared, and then the second active portion 31 is prepared, so that the length of the second channel sub-portion 313 between the second source 53 and the second drain 54 can be controlled by controlling the distance between the second source 53 and the second drain 54 to achieve the second transistor T2 having a short channel.

The inorganic passivation layer 75 covering the second metal layer 50 and the second active layer 30 is formed on the second insulating layer 74.

S40. Forming the first metal layer 40 on the side of the second active layer 30 away from the first active layer 20. The first metal layer 40 includes the second gate 41 of the second transistor T2, and the second gate 41 is formed on the side of the second active portion 31 away from the first active portion 21.

In step S40, a second metal material layer is formed on a side of the inorganic passivation layer 75 away from the second active layer 30. The second metal material layer is patterned to obtain the first metal layer 40. The first metal layer 40 includes the second gate 41 formed on the side of the second active portion 31 away from the first active portion 21, and the adapting portion 42 located above the first drain 52. The adapting portion 42 is connected to the first drain 52 through the inorganic passivation layer 75.

In the embodiments of the present disclosure, the second active portion 31 includes the second source contact sub-portion 311 on the side of the second source 53 away from the first active portion 21, the second drain contact sub-portion 312 on the side of the second drain 54 away from the first active portion 21, and the second channel sub-portion 313 is connected between the second source contact sub-portion 311 and the second drain contact sub-portion 312.

In an embodiment, the orthographic projection of the second channel sub-portion 313 on the base 10 is within the coverage area of the orthographic projection of the light-shielding layer 17 on the base 10, so that the light from the base 10 can be blocked from being irradiated to the second channel sub-portion 313 of the second active portion 31, thereby further improving the stability of the second transistor T2.

In an embodiment, the second channel sub-portion 313 is connected between the second source 53 and the second drain 54. After the voltage is applied to the second gate 41, a current channel may be formed in the second channel sub-portion 313, and then a current channel may be formed directly between the second source 53 and the second drain 54, without performing the conductorization process to the second active portion 31.

It is to be noted that in the embodiments of the present disclosure, by disposing the second gate 41 on the second active portion 31 and increasing the coverage area of the second gate 41, the second channel sub-portion 313 corresponding to the second gate 41 is connected between the second source 53 and the second drain 54, a current channel can be directly formed between the second source 53 and the second drain 54, so that the second active portion 31 does not need the conductorization process. Therefore, the conductorization process can be omitted, and the phenomenon that carrier diffusion occurs due to the influence of the thermal process on the second active portion 31 can be avoided, thereby improving the stability and yield of the second transistor T2.

In addition, in the embodiments of the present disclosure, since the area of the electrode plate 62 is large, and the second gate 41 of the second transistor T2 is disposed on the side of the second active portion 31 away from the first active portion 21, a spatial interference between the second gate 41 and the electrode plate 62 can be avoided, and parasitic capacitance can be reduced, thereby improving the reliability and stability of the display panel.

Then, the organic planarization layer 76 covering the first metal layer 40 is formed on the side of the first metal layer 40 away from the second active layer 30.

Next, the anode layer 80 is formed on the side of the organic planarization layer 76 away from the first metal layer 40. The anode layer 80 includes the anode 81 electrically connected to the first transistor T1, and the anode 81 is electrically connected to the first drain 52. Further, the anode 81 is electrically connected to the first drain 52 by the adapting portion 42.

Here, the orthographic projection of the second channel sub-portion 313 on the base 10 is located within the coverage area of the orthographic projection of the anode 81 on the base 10, so that light from the side of the second active portion 31 away from the base 10 can be blocked from being irradiated to the second channel sub-portion 313, thereby further improving the stability of the second transistor T2.

Next, the pixel definition layer 77 covering the anode layer 80 is formed on the organic planarization layer 76. A pixel opening is formed in the pixel definition layer 77 to expose a portion of the upper surface of the anode 81.

According to the embodiments of the present disclosure, the first active portion 21 of the first transistor T1 at least partially overlaps the second active portion 31 of the second transistor T2, so that the first transistor T1 at least partially overlaps the second transistor T2, thereby effectively reducing the occupied space of the first transistor T1 and the second transistor T2, and improving the space utilization rate and the resolution of the display panel. In addition, in the embodiments of the present disclosure, the second gate 41 of the second transistor T2 is disposed on the side of the second active portion 31 away from the first active portion 21, so that spatial interference between the second gate 41 and the electrode plate can be avoided, parasitic capacitance can be reduced, and the reliability and stability of the display panel can be improved.

In addition, an embodiment of the present disclosure further provides a display device including the display panel described in the above embodiments and a device body, and the display panel and the device body are integrated with each other.

The device body may include a middle frame, a frame glue, and the like. The display device may be a display terminal such as a mobile phone, a tablet computer, or a television, which is not limited herein.

In the above embodiments, the description of each embodiment has its own focus, and parts not described in detail in a certain embodiment may be referred to the related description of other embodiments.

The above provides a detailed description of a display panel and a display device according to the embodiments of the present disclosure, and specific examples are applied herein to illustrate the principles and implementation of the present disclosure. The description of the above embodiments is merely used to help understand the technical solutions of the present disclosure and its core ideas. It will be understood by those of ordinary skill in the art that modifications may still be made to the technical solutions described in the foregoing embodiments, or equivalent substitutions may be made to some of the technical features therein. These modifications or substitutions do not make the essence of the corresponding technical solutions out of the scope of the technical solutions of the embodiments of the present disclosure.

What is claimed is:

1. A display panel, comprising a first transistor and a second transistor electrically connected to each other, wherein the first transistor comprises a first active portion made of a low-temperature polysilicon material, and the second transistor comprises a second active portion made of a metal oxide material and a second gate:
wherein the display panel further comprises:
a base;
a first active layer disposed on the base and comprising the first active portion;
a second active layer disposed on a side of the first active layer away from the base and comprising the second active portion located on a side of the first active portion away from the base; and
a first metal layer disposed on a side of the second active layer away from the first active layer and comprising the second gate located on a side of the second active portion away from the first active portion;
wherein an orthographic projection of the second active portion on the base at least partially overlaps an orthographic projection of the first active portion on the base.

2. The display panel according to claim 1, wherein the second transistor further comprises a second source and a second drain, the display panel further comprises a second metal layer disposed between the second active layer and the first active layer, the second metal layer comprises the second source and the second drain, which are connected to two ends of the second active portion, respectively.

3. The display panel according to claim 2, wherein the second active portion comprises a second source contact sub-portion located on a side of the second source away from the first active portion, a second drain contact sub-portion located on a side of the second drain away from the first active portion, and a second channel sub-portion connected between the second source contact sub-portion and the second drain contact sub-portion, and the second channel sub-portion is located between the second source and the second drain.

4. The display panel according to claim 3, wherein each of a resistivity of a material of the second source contact sub-portion and a resistivity of a material of the second drain contact sub-portion is equal to a resistivity of a material of the second channel sub-portion.

5. The display panel according to claim 2, wherein the first transistor comprises a first source and a first drain connected to two ends of the first active portion, respectively; and
the second metal layer further comprises the first source and the first drain, and the second active portion is between the first source and the first drain.

6. The display panel according to claim 5, wherein the first active portion comprises a first source contact sub-portion connected to the first source and a first drain contact sub-portion connected to the first drain, and the second source is electrically connected to the first drain contact sub-portion.

7. The display panel according to claim 6, wherein the first source is spaced apart from the second drain.

8. The display panel according to claim 6, further comprising a light-shielding layer disposed in the base, wherein the first active portion further comprises a first channel sub-portion connected between the first source contact sub-portion and the first drain contact sub-portion, and both of an orthographic projection of the first channel sub-portion on the base and an orthographic projection of the second channel sub-portion on the base are within an orthographic projection of the light-shielding layer on the base.

9. The display panel according to claim 5, further comprising an anode layer disposed on a side of the first metal layer away from the second active layer, wherein the anode layer comprises an anode electrically connected to the first transistor; and
the first metal layer comprises an adapting portion located between the anode and the first drain, and the anode is connected to the first drain by the adapting portion.

10. The display panel according to claim 9, wherein an orthographic projection of the second channel sub-portion on the base is located within an orthographic projection of the anode on the base.

11. The display panel according to claim 9, further comprising an inorganic passivation layer and an organic planarization layer disposed between the second active layer and the anode layer, wherein the inorganic passivation layer covers the second active portion, and the organic planarization layer covers the inorganic passivation layer.

12. The display panel according to claim 3, wherein the first transistor further comprises a first gate disposed between the first active portion and the second active portion, and an electrode plate disposed between the first gate and the second active portion; and
an orthographic projection of the second channel sub-portion on the base is located in an orthographic projection of the first gate on the base, and/or the orthographic projection of the second channel sub-portion on the base is located in an orthographic projection of the electrode plate on the base.

13. A display device, comprising a display panel, wherein the display panel comprises a first transistor and a second transistor electrically connected to each other, the first transistor comprises a first active portion made of a low-temperature polysilicon material, and the second transistor comprises a second active portion made of a metal oxide material and a second gate:
the display panel further comprises:
a base;
a first active layer disposed on the base and comprising the first active portion;
a second active layer disposed on a side of the first active layer away from the base and comprising the second active portion located on a side of the first active portion away from the base; and
a first metal layer disposed on a side of the second active layer away from the first active layer and comprising the second gate located on a side of the second active portion away from the first active portion;
wherein an orthographic projection of the second active portion on the base at least partially overlaps an orthographic projection of the first active portion on the base.

14. The display device according to claim 13, wherein the second transistor further comprises a second source and a second drain, and wherein the display panel further comprises a second metal layer disposed between the second active layer and the first active layer and comprising the second source and the second drain, which are connected to two ends of the second active portion, respectively.

15. The display device according to claim 14, wherein the second active portion comprises a second source contact sub-portion located on a side of the second source away from the first active portion, a second drain contact sub-portion located on a side of the second drain away from the first active portion, and a second channel sub-portion connected between the second source contact sub-portion and the second drain contact sub-portion, and the second channel sub-portion is located between the second source and the second drain.

16. The display device according to claim 15, wherein each of a resistivity of a material of the second source contact sub-portion and a resistivity of a material of the second drain contact sub-portion is equal to a resistivity of a material of the second channel sub-portion.

17. The display device according to claim 14, wherein the first transistor comprises a first source and a first drain connected to two ends of the first active portion, respectively; and
the second metal layer further comprises the first source and the first drain, and the second active portion is between the first source and the first drain.

18. The display device according to claim 17, wherein the first active portion comprises a first source contact sub-portion connected to the first source and a first drain contact sub-portion connected to the first drain, and the second source is electrically connected to the first drain contact sub-portion.

19. The display device according to claim 18, wherein the first source is spaced apart from the second drain.

20. The display device according to claim 18, further comprising a light-shielding layer disposed in the base, wherein the first active portion further comprises a first channel sub-portion connected between the first source contact sub-portion and the first drain contact sub-portion, and both of an orthographic projection of the first channel sub-portion on the base and an orthographic projection of the second channel sub-portion on the base are within an orthographic projection of the light-shielding layer on the base.
